(19) United States
(12) Patent Application Publication
(10) Pub. No.: US 2008/0111748 A1
(43) Pub. Date: May 15, 2008

(54) ANTENNA SYSTEM HAVING PLURAL SELECTABLE ANTENNA FEED POINTS AND METHOD OF OPERATION THEREOF

(76) Inventors: Doug L. Dunn, Chula Vista, CA (US); Gregory Poilasne, San Diego, CA (US); Henry S. Chang, San Diego, CA (US)

Correspondence Address: KYOCERA WIRELESS CORP., P.O. BOX 928289, SAN DIEGO, CA, 92192-8289, US

(21) Appl. No.: 11/558,841

(22) Filed: Nov. 10, 2006

(51) Int. Cl. G01R 29/08; H01Q 1/24; H01Q 3/24

(52) U.S. Cl. 343/702; 343/876; 343/703

(57) ABSTRACT

An antenna system includes a plurality of antenna feed points operatively coupled to one or more antennas and a controller for selecting at least one of the antenna feed points based on the operating environment of the antenna system. When the antenna system is employed in a mobile wireless device, selecting a particular antenna feed point can modify the device's surface current distribution to improve the antenna system's performance over the effects of near field conditions.

### TECHNICAL FIELD

The invention relates in general to wireless communication systems and more specifically to an antenna system having at least one antenna with selectable feed points.

### BACKGROUND

Wireless communications devices typically transmit and receive electromagnetic signals through antennas. The performance of a wireless device's antenna system is often challenged by the device's near field environment. With small mobile devices, such as wireless handsets, the near field environment is primarily affected by the user and other external objects in close proximity to the device. For example, the way the user holds a handset or places a handset on or near an object may affect surface currents in the device, which may in turn degrade the performance of the handset's antenna system. Prior attempts to improve antenna performance in light of near-field effects have not been generally practicable for small wireless devices because such attempts have proposed antenna systems that are relatively large, complex and costly.

Accordingly, there is a need for an improved antenna system that can adjust to the influence of near field conditions and that is suitable for use in portable wireless handsets.

### SUMMARY

It is an advantage of the present invention to provide an antenna system that is suitable for use with portable wireless communication devices and that can adjust in response to the operating environment of the antenna system.

In accordance with an exemplary embodiment of the invention, an antenna system includes a plurality of antenna feed points operatively coupled to one or more antennas and a controller for selecting at least one of the antenna feed points based on the operating environment of the antenna system. When the antenna system is employed in a mobile wireless device, selecting a particular antenna feed point can modify the device's surface current distribution to improve the antenna system's performance over the effects of near field conditions.

Other aspects, features, embodiments, methods and advantages of the invention will be or will become apparent to one with skill in the art upon examination of the following figures and detailed description. It is intended that all such additional features, embodiments, processes and advantages be included within this description, be within the scope of the invention, and be protected by the accompanying claims.

### BRIEF DESCRIPTION OF THE DRAWINGS

It is to be understood that the drawings are solely for purpose of illustration and do not define the limits of the invention. Furthermore, the components in the figures are not necessarily to scale, emphasis instead being placed upon illustrating the principles of the invention. In the figures, like reference numerals designate corresponding parts throughout the different views.

FIG. 1 is a block diagram of a portable communication device including an antenna system having selectable antenna feed points in accordance with an exemplary embodiment of the invention.

FIG. 2 is a detailed diagram of an exemplary symmetrical antenna included in the communication device shown in FIG. 1.

FIG. 3 is a detailed block diagram of an antenna feed point switch included in the communication device shown in FIG. 1.

FIG. 4 is flowchart of a method of operating the antenna system shown in FIG. 1.

### DETAILED DESCRIPTION

The following detailed description, which references to and incorporates the drawings, describes and illustrates one or more specific embodiments of the invention. These embodiments, offered not to limit but only to exemplify and teach the invention, are shown and described in sufficient detail to enable those skilled in the art to practice the invention. Thus, where appropriate to avoid obscuring the invention, the description may omit certain information known to those of skill in the art.

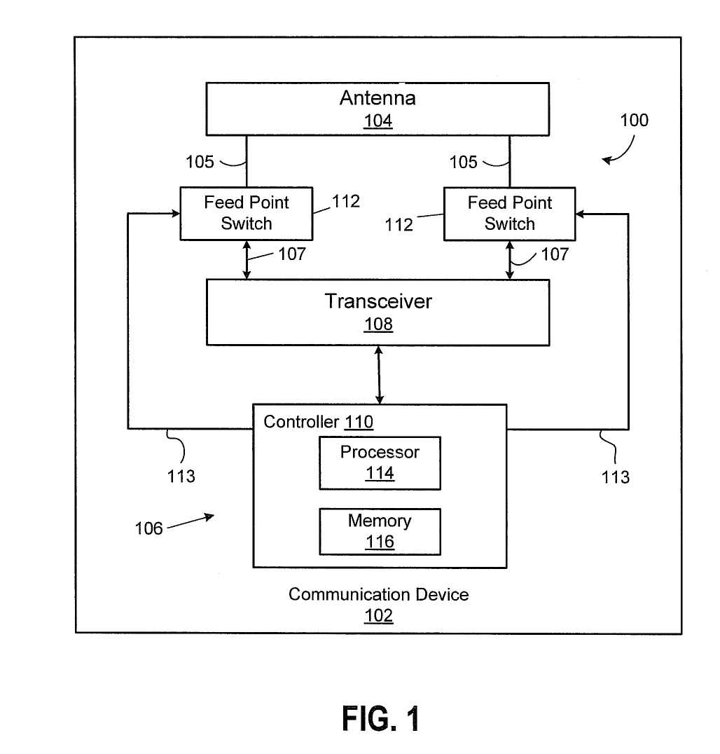

FIG. 1 is a block diagram of a portable communication device 102 including an antenna system 100 in accordance with an exemplary embodiment of the invention. In the exemplary embodiment, the communication device 102 is a portable wireless communication device such as a cellular telephone or personal digital assistant (PDA). However, in some circumstances, the communication device 102 may be a fixed device such as a base station or access point. In the example shown in FIG. 1, the antenna system 100 includes at least a portion of the communication device 102, i.e., the antenna 104, the antenna feed points 105, the feed point switches 112, and portions of the controller 110.

The communication device 102 includes an antenna 104 that can be coupled to a communication circuit 106 through any one of a plurality of antennas feed points 105. The communication circuit 106 includes a plurality of feed point switches 112, each corresponding to a respective antenna feed point 105, a radio frequency (RF) transceiver 108, and a controller 110 for selecting at least one of the antenna feed points 105 based on the operating environment of the communication device 102.

The transceiver 108 receives and transmits signals through the antenna system 100. Cellular handset transceivers suitable for use in the communication device 102 are well known to those skilled in the art, and thus, further details of the transceiver 108 are not provided herein.

The controller 110 is configured to detect operational parameters associated with the communication device 102. The operational parameters may include any combination of parameters measured at the communication device 102 and/or parameters measured at a device that is in RF communication with the communication device 102. The operational parameters are generally indicative of the antenna system's current operating environment and/or performance.

Preferably, the controller 110 selects the antenna feed point 105 based on operational parameters that are indicative of the near field environment of the antenna system 100. For example, the controller 110 can detect near field conditions, such as the antenna's input impedance, return loss, or current distribution, and/or the antenna system's proximity to other objects using proximity-detection techniques, for example, such as those disclosed in U.S. Pat. No. 6,657,595 to Motorola, Inc., which is hereby incorporated by reference.

The operational parameters can also include operational parameters that are commonly measured and/or calculated in conventional cellular communication systems such as CDMA systems. These additional operational parameters include the signal-to-noise ratio (SNR) of RF signals passed between the communication device 102 and other devices (e.g., a cellular base station), the output power (Pₒ) of RF signals emitted from the communication device 102, closed-loop power control bits sent by a base station for the communication device 102, automatic gain control (AGC) set points of the communication device 102, an antenna reflection coefficient associated with the antenna 104, frame error rate (FER), bit error rate (BER), E_{b}/Nₜ, and E_{c}/Iₒ measured for a pilot signal The Eb/Nt and Ec/Io are parameters used at the mobile station for monitoring the forward link. If the selection of the antenna feed point affects the RF signal received by the communication device 102, then these parameters can be used. Generally, these two parameters are monitored to make sure that the incoming RF signal is not degraded by the antenna feed point selection. Operational parameters other than those enumerated above may also be used. The controller 110 may rely upon any suitable combination of the foregoing operational parameters to determine the optimum antenna feed point.

In conventional cellular systems, SNR is measured at a base station for the reverse link, and it is not typically sent to the communication device 102. The FER and BER are parameters calculated at the base station and also are not typically available at the communication device 102. However, for purposes of antenna feed point selection, software in the base station can transmit these parameters as additional control data through the forward link. The SNR, FER, BER may be sent to the communication device 102 through signaling messages. These messages may be sent by the base station autonomously, periodically or upon request by the device.

In response to the operational parameters, the controller 110 selects at least one of the antenna feed points 105 to couple the antenna 104 to the transceiver 108. Preferably, the controller 110 selects a single antenna feed point 105. However, in some circumstances, the controller 110 can be configured to select a combination of multiple feed points 105 for coupling to the transceiver 108.

The controller 110 selects an antenna feed point 105 by comparing one or more of the operational parameters. The comparisons may be relative, i.e., between different measurements of an operational parameter made at different times, or absolute, i.e., between operational parameters and desired threshold values. The particular operational parameters and comparisons relied on depend upon the specific implementation of the communication device 102 and the communication system in which it is used. For example, in a CDMA system, the controller 110 could be configured to detect power control bit settings when each of the antenna feed points 105 is individually coupled to the communication circuit 106. The controller 110 would then select the antenna feed point 105 that corresponds to the lowest accumulated values of the power control bits, since this setting corresponds to the optimum performance of the antenna system 102. This particular determination can also be described in terms of slope, since the optimum antenna feed point would produce the most negative slope (e.g., ⅔ is more negative than 1), where the slope is the average of the power control bits over a specified period of time.

The particular antenna feed point 105 that is selected is chosen to improve antenna system 100 performance. During operation, the controller 110 generates control signals 113 to select one or more of the antenna feed points 105 in order to optimize performance of the antenna system 100. The control signals 113 are generated based on the comparisons of the operational parameters.

The controller 110 is any device, circuit, integrated circuit (IC), application specific IC (ASIC), or other configuration including any combination of hardware, software and/or firmware that performs the functions described herein as well as facilitating the overall functionality of the communication device 102. In the exemplary embodiment, the controller 110 includes a processor 114 and a memory 116. The processor 114 is any computer, processor, microprocessor, or processor arrangement that executes software code to perform the calculation and control functions described herein. The memory 116 is any memory device, IC, or memory medium suitable for storing software code and data that can be accessed by the processor 114. The controller 110 may include other devices, circuits and elements not shown in FIG. 1 that facilitate the exchange of signals and perform other interface functions.

In some situations, the antenna feed point 105 is changed during transmission or reception of RF signals. In other circumstances, operational parameters obtained during previous transmissions or receptions are used to configure the antenna feed points before the next transmission or reception. Further, in some circumstances, antenna feed point changes are made without transmitting or receiving a data or voice signal.

The antenna system 104, communication circuit 106 and communication device 102 may include other hardware, software, firmware, or other arrangements of such components not shown in FIG. 1 for facilitating and performing the functions of a communication device 102. For example, the communication device 102 may include input and output devices such as keypads, displays, microphones and speakers. Further, the functions and operations of the blocks described in FIG. 1 may be implemented in any number of devices, circuits, or elements. Two or more of the functional blocks may be integrated in a single device and the functions described as performed in any single device may be implemented over several devices. For example, the transceiver 106 can be implemented as a separate transmitter and receiver in some circumstances.

Although FIG. 1 shows the antenna system 100 having a single, shared antenna 104, the selectable antenna feed point approach disclosed herein can be applied to other antenna systems comprising any suitable configuration or number of antennas and antenna feed points. For example, separate transmit and receive antennas could be substituted for the antenna 104, where one or more of the antennas has multiple feed points. In addition, the receive antenna could be an entirely separate structure from the communication device 102. Also, a receive diversity antenna system with multiple receive antenna and a switched transmit antenna could be used instead of the single antenna 104. Examples of such receive diversity antenna systems are discussed in further detail in U.S. patent application Ser. No. 11/353,267, entitled “Antenna System Having Receive Antenna Diversity and Configurable Transmission Antenna and Method of Management Thereof,” filed Feb. 13, 2006, which is incorporated by reference in its entirety herein.

It is also noted that the transmit (TX) and receive (RX) antenna feed points may be separate. For example, the transceiver 108 TX and RX signals may be coupled to antenna feed point 1, but only the TX signal can switch between antenna feed point 1 and antenna feed point 2. In this configuration, the transceiver RX signal only connects to antenna feed point 1. In a frequency-division duplexing (FDD) system, there could be significant differences in the antenna system characteristics where the optimum solution for one path (TX or RX) is not the optimum solution for the other. On one hand, if the communication device is using antenna diversity, making the switch on a shared TX/RX antenna might not make a difference, whereas in a non-diversity communication device, the switch might cause degradation in antenna performance.

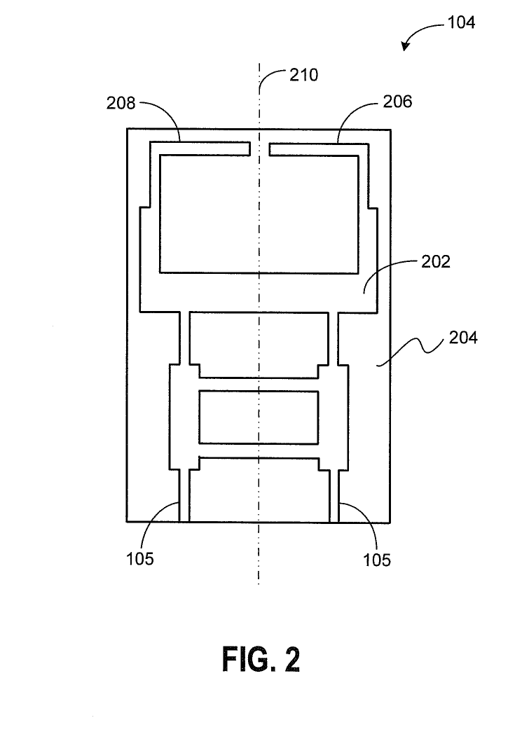

FIG. 2 is a detailed diagram of the exemplary symmetrical antenna 104 included in the communication device 102 shown in FIG. 1. The antenna 104 is a shared antenna that receives and transmits RF signals. Where the antenna 104 is a shared antenna, the antenna feed point selection can be based, at least in part, on RF signal direction through the antenna 104, i.e., whether the communication device 102 is transmitting or receiving RF signals. Thus, different antenna feed points can be used for transmitting and receiving RF signals. In this situation, the controller 110 is configured to detect traffic direction as an operational parameter.

The antenna 104 is a capacitively-loaded magnetic dipole antenna that includes an electrically-conductive antenna element 202 printed on a dielectric substrate 204 using conventional manufacturing techniques. The antenna element 202 is composed of two symmetrical portions 206, 208 that are symmetrical about an axis 210. Each symmetrical portion includes a corresponding antenna feed point 105.

A significant advantage of the communication device 102 is that the antenna system 100 is configured so that the selection of a particular antenna feed point 105 does not substantially vary the operation of the antenna 104. For example, the geometry and layout of the antenna 104 and antenna feed points 105 are designed so that the frequency response and electrical length of the antenna 104 does not vary substantially with the selection of a particular antenna feed point 105. This is important in order to maintain communications over desired RF channels in a communication system.

Although a specific type of antenna is illustrated in FIG. 2, the antenna 104 is exemplary only and other types of antennas may be used in the antenna system 100. In some circumstances, the antenna 104 may be any dipole, loop, patch, Planar Inverted “F” (PIFA), inverted F, monopole, folded monopole, balanced antenna, or stubby antenna that can exchange signals with a communication system. The particular antenna type of antenna used in the antenna system 100 is selected based on the operating frequencies, bandwidth, and power levels used by the communication device 102, and in accordance with other design considerations such as efficiency, size, impedance, durability, gain, polarization, cost, industrial design, and weight.

Where the antenna system 100 includes a plurality of antennas, the controller 110 selects one or more of the antennas by generating control signals 113 to control the feed point switches 105 to connect the selected antenna(s).

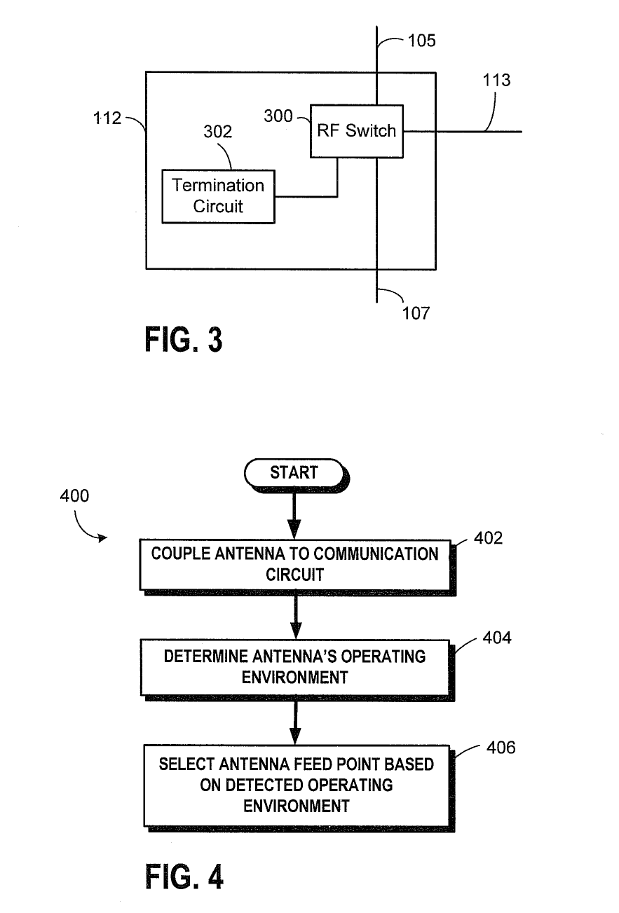

FIG. 3 is a detailed block diagram of one of the antenna feed point switches 112 included in the communication device 102 shown in FIG. 1. The antenna feed point switch 112 includes an RF switch 300 and an optional termination circuit 302. The RF switch 300 selectively couples the antenna feed point 105 to either the transceiver input 107 or termination circuit 302 in response to the control signals 113 from the controller 110. When the control signals 113 indicate that the antenna feed point 105 has been selected, the RF switch 300 couples the antenna feed point to the transceiver input 107. When the control signals 113 indicate that the antenna feed point 105 has not been selected, the RF switch 300 terminates the antenna feed point 105 in an appropriate manner and also decouples the transceiver input 107 from the antenna feed point 105.

The RF switch 300 is any suitable switch, variable impedance device, or combination thereof, including passive switching elements like transistors, diodes, micro electromechanical systems (MEMS) or the like, that is responsive to the control signals 113.

The termination circuit 302, if needed, terminates an unused antenna feed point 105 with an optimum termination suited to the antenna 104. The termination can be an open, load or short. The type of termination and load depends on the particular design of the antenna 104 and antenna feed points 105.

Duplexers, diplexers and/or additional switches (not shown) may also be used in coupling the antenna 104 to the transceiver 108.

FIG. 4 is flowchart 400 of a method of operating the antenna system 100 shown in FIG. 1. The exemplary method is performed within the communication device 102 and includes executing software code in the controller 110. The method, however, may be performed using any combination of hardware and/or software in any type of device. The execution of the steps may occur in an order other than shown in FIG. 4, including the simultaneous performance of one or more steps.

At step 402, the antenna 104 is coupled to the communication circuit 106 at a first antenna feed point.

At step 404, the controller 110 determines the effects of the operating environment on the antenna's performance. As discussed above in connection with FIG. 1, this step involves detecting, measuring and/or calculating operational parameters, either at the communication device 102 or externally (e.g., at a base station), that are indicative of the antenna's current operating environment and/or performance. The operational parameters can be determined for each antenna feed point 105 by alternatively coupling the communication circuit 106 to each antenna feed point 105 and determining the operational parameters associated with the respective antenna feed point 105. Additionally or alternatively, the controller 110 can detect near field conditions, such as the antenna's input impedance, return loss, or current distribution, and/or the antenna system's proximity to other objects, as discussed above in connection with FIG. 1. In some circumstances, determining operational parameters for each antenna feed point only needs to be done if the operational parameters are at or beyond a desired threshold.

At step 406, the controller 110 selects an optimal antenna feed point based on the ascertained operational parameters. The selection process is based on one or more comparisons of the operational parameters, such as the comparisons discussed above in connection with FIG. 1. The controller 110 issues control signals 113 causing the respective feed point switches 112 to decouple and terminate the first antenna feed point and couple the optimal antenna feed point to the transceiver input 107.

Other embodiments and modifications of this invention will occur readily to those of ordinary skill in the art in view of these teachings. The above summary and description is illustrative and not restrictive. The invention is to be limited only by the following claims, which include all such embodiments and modifications when viewed in conjunction with the above specification and accompanying drawings. The scope of the invention should, therefore, not be limited to the above summary and description, but should instead be determined by the appended claims along with their full scope of equivalents.

What is claimed is:

1. An antenna system, comprising:
a plurality of antenna feed points operatively coupled to one or more antennas; and
a controller configured to select at least one of the antenna feed points based on an operating environment of the antenna system.

2. The antenna system of claim 1, wherein the controller is further configured to select the antenna feed point based on a near field environment of the antenna system.

3. The antenna system of claim 1, wherein the controller is further configured to determine the operating environment of the antenna system.

4. The antenna system of claim 3, wherein the controller is further configured to determine the operating environment based on operational parameters selected from the group consisting of signal-to-noise ratio (SNR), output power (Po), power control bits, automatic gain control (AGC) set points, an antenna reflection coefficient, frame error rate (FER), bit error rate (BER), Eb/Nt, Ec/Io, near field conditions, the antenna system's proximity to other objects and any suitable combination of the foregoing operational parameters.

5. The antenna system of claim 1, further comprising a termination circuit for selectively terminating unused antenna feed points with one or more predetermined terminations.

6. The antenna system of claim 1, wherein each of the antennas has a predetermined frequency response and antenna system is configured so that the selection of the antenna feed point does not substantially vary the frequency responses of the antennas.

7. A method for operating an antenna system, the method comprising:
communicably coupling an antenna to a communication circuit at a first antenna feed point;
determining effects of the operating environment on the antenna's performance; and communicably coupling the antenna to the communication circuit at a second antenna feed point in response to the effects of the operating environment.

8. The method of claim 7, further comprising:
determining the antenna's performance using the first antenna feed point;
determining the antenna's performance using the second antenna feed point;
communicably decoupling the second antenna feed point from the communication circuit based on a comparison of the antenna's performances using the first and second antenna feed points; and
communicably coupling the antenna to the communication circuit at the first antenna feed point based on the comparison of the antenna's performances using the first and second antenna feed points.

9. The method of claim 7, further comprising the step of:
decoupling the antenna from the communication circuit at the first antenna feed point.

10. The method of claim 7, further comprising the step of:
terminating the first antenna feed point with a predetermined termination.

11. The method of claim 7, wherein the antenna has an electrical length and the act of communicably coupling the antenna to the communication circuit at the second antenna feed point does not substantially vary the electrical length of the antenna.

12. The method of claim 7, wherein the antenna has a frequency response and the act of communicably coupling the antenna to the communication circuit at the second antenna feed point does not substantially vary the frequency response of the antenna.

13. The method of claim 7, wherein the step of determining includes:
calculating operational parameters at a base station;
sending the operational parameters to a portable communication device including the communication circuit; and
determining the effects of the operating environment based on the operational parameters.

14. A portable wireless device, comprising:
an antenna;
a plurality of antenna feed points operatively coupled to the antenna, each of the antenna feed points providing a different current distribution on the antenna; and
a controller for determining operational parameters of the portable wireless device and for selecting at least one of the antenna feed points based on the determined operational parameters to improve antenna performance.

15. The portable wireless device of claim 14, further comprising a plurality of antennas having a plurality of antenna feed points selectable by the controller.

16. The portable wireless device of claim 14, wherein the antenna is a symmetrical, printed antenna.

17. The portable wireless device of claim 14, wherein the antenna is a shared antenna that receives and transmits radio frequency (RF) signals and the antenna feed point selection is based, at least in part, on RF signal direction through the antenna.

18. The portable wireless device of claim 14, further comprising termination means for selectively terminating unused antenna feed points with one or more predetermined terminations.

19. The portable wireless device of claim 14, wherein the operational parameters are selected from the group consisting of signal-to-noise ratio (SNR), output power (Po), power control bits, automatic gain control (AGC) set points, an antenna reflection coefficient, frame error rate (FER), bit error rate (BER), Eb/Nt, Ec/Io, near field conditions, the portable wireless device's proximity to other objects and any suitable combination of the foregoing operational parameters.

20. The portable wireless device of claim 14, wherein the antenna and the antenna feed points are configured so that the frequency response of the antenna does not vary substantially as a function of antenna feed point selection.
